(19) United States
(12) Patent Application Publication
(10) Pub. No.: US 2017/0045832 A1
(43) Pub. Date: Feb. 16, 2017

(54) Cleaning Apparatus and Associated Low Pressure Chamber Apparatus

(71) Applicant: ASML Netherlands B.V., Veldhoven (NL)

(72) Inventors: Freek Theodorus MOLKENBOER, Heerjansdam (NL); Jeremy BURKE, San Diego, CA (US); Wilhelm CLAUSSEN, Wuerselen (DE); Alexander Franciscus DEUTZ, Leiden (NL); Jerry Don HODO, San Diego, CA (US); Cornelia Elizabeth Carolina HULSBOSCH-DAM, Schoonhoven (NL); Edwin TE SLIGTE, Eindhoven (NL); Mayk VAN DEN HURK, Veldhoven (NL)

(73) Assignee: ASML Netherlands B.V., Veldhoven (NL)

(21) Appl. No.: 15/303,604

(22) PCT Filed: Apr. 9, 2015
(86) PCT No.: PCT/EP2015/057674

§ 371 Date: Oct. 12, 2016

Related U.S. Application Data
(60) Provisional application No. 61/987,166, filed on May 1, 2014.

(51) Int. Cl. G03F 7/20

(52) U.S. Cl. CPC G03F 7/70925; G03F 7/70033

(57) ABSTRACT

Disclosed is a cleaning apparatus configured to clean a radiation transmission assembly (such as a viewport), or part thereof. The radiation transmission assembly provides for radiation transmission to and/or from a low pressure chamber. The cleaning apparatus comprises, a hydrogen radical generator configured to generate hydrogen radicals for use in cleaning said radiation transmission assembly or part thereof, and a connection assembly for connection to said radiation transmission assembly.

### CROSS-REFERENCE TO RELATED APPLICATIONS

The application claims the benefit of U.S. provisional application 61/987,166, which was filed on 1 May 2014, and which is incorporated herein in its entirety by reference.

### FIELD

The present invention relates to cleaning apparatus and associated low pressure chamber apparatus. In particular it relates to a cleaning apparatus for a viewport assembly forming part of a low pressure chamber apparatus, such as that forming part of an EUV radiation source.

### BACKGROUND

Extreme ultraviolet (EUV) radiation is electromagnetic radiation having a wavelength within the range of 5-20 nm, and may be produced using a plasma. A radiation system for producing EUV radiation may include a laser for exciting a fuel to provide the plasma, and a source collector apparatus for containing the plasma. The plasma may be created, for example, by directing a laser beam at a fuel, such as particles of a suitable material (e.g., tin), or a stream of a suitable gas or vapor, such as Xe gas or Li vapor. The resulting plasma emits output radiation, e.g., EUV radiation, which is collected using a radiation collector. The radiation collector may be a mirrored normal incidence radiation collector, which receives the radiation and focuses the radiation into a beam. The source collector apparatus may include an enclosing structure or chamber arranged to provide a vacuum environment to support the plasma. Such a radiation system is typically termed a laser produced plasma (LPP) source.

One application of an EUV radiation source is in lithography. A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned.

In order to reduce the minimum printable size, imaging may be performed using radiation having a short wavelength. It has therefore been proposed to use an EUV radiation source providing EUV radiation within the range of 13-14 nm, for example. It has further been proposed that EUV radiation with a wavelength of less than 10 nm could be used, for example within the range of 5-10 nm such as 6.7 nm or 6.8 nm. Such radiation is termed extreme ultraviolet radiation or soft x-ray radiation.

An EUV radiation source may comprise viewports for performing metrology and monitoring operations. Such viewports may comprise pellicles that transmit radiation and through which the necessary measurements are made. These pellicles can become contaminated with fuel debris and require regular replacement.

### SUMMARY

It is desirable to mitigate for the effect of contamination of these viewports.

The invention in a first aspect provides a cleaning apparatus configured to clean a radiation transmission assembly or part thereof, said radiation transmission assembly providing for radiation transmission to and/or from a low pressure chamber; said cleaning apparatus comprising: a hydrogen radical generator configured to generate hydrogen radicals for use in cleaning said radiation transmission assembly or part thereof; and a connection assembly for connection to said radiation transmission assembly.

The invention in a second aspect provides for a low pressure chamber apparatus comprising one or more radiation transmission assemblies through which radiation may be transmitted for monitoring operations, wherein one or more of said radiation transmission assemblies comprises a cleaning apparatus configured to clean its corresponding radiation transmission assembly or part thereof, each cleaning apparatus comprising a hydrogen radical generator configured to generate hydrogen radicals for use in cleaning said radiation transmission assembly or part thereof.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present invention and, together with the description, further serve to explain the principles of the invention and to enable a person skilled in the relevant art(s) to make and use the invention. Embodiments of the invention are described, by way of example only, with reference to the accompanying drawings, in which:

FIG. 1 depicts schematically a lithographic apparatus having reflective projection optics;

FIG. 2 is a more detailed view of the apparatus of FIG. 1; and

FIG. 3 shows an alternative source arrangement usable in the apparatus of FIG. 2;

FIG. 4 shows a viewport cleaning apparatus according to an embodiment of the invention, in top down view; and

FIG. 5 shows the viewport cleaning apparatus of FIG. 4 in cross-section.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements.

### DETAILED DESCRIPTION OF EXEMPLARY EMBODIMENTS

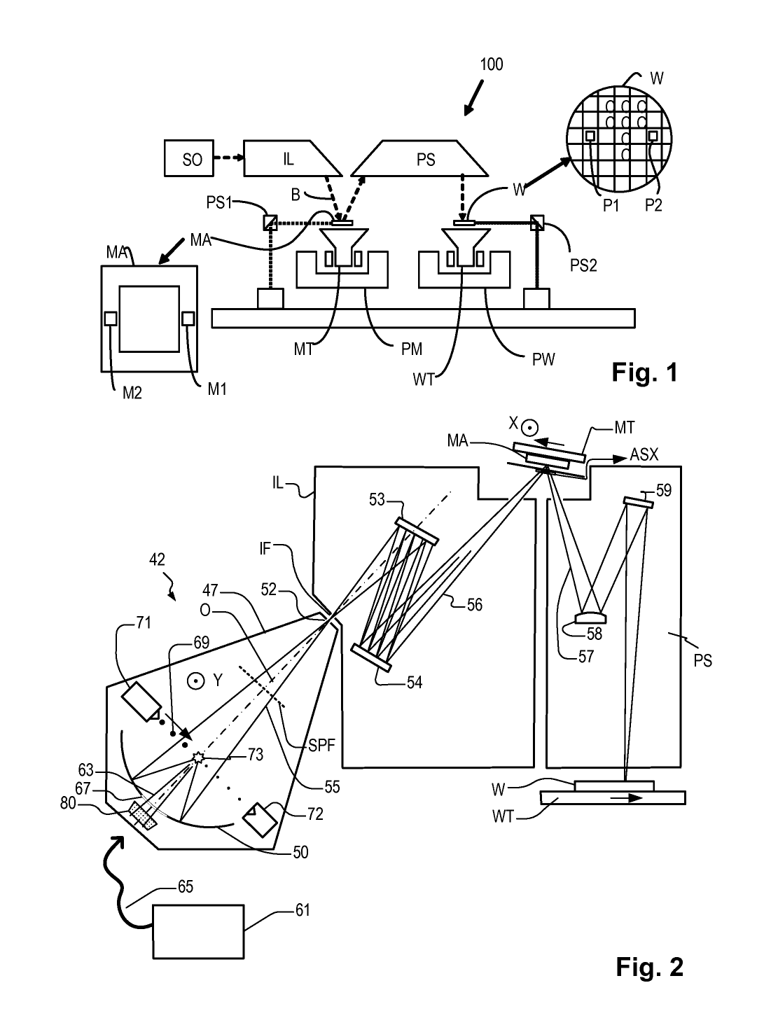

FIG. 1 schematically depicts a lithographic apparatus 100 including a source module SO according to one embodiment of the invention. The apparatus comprises:

an illumination system (illuminator) IL configured to condition a radiation beam B (e.g., EUV radiation).

a support structure (e.g., a mask table) MT constructed to support a patterning device (e.g., a mask or a reticle) MA and connected to a first positioner PM configured to accurately position the patterning device;

a substrate table (e.g., a wafer table) WT constructed to hold a substrate (e.g., a resist-coated wafer) W and connected to a second positioner PW configured to accurately position the substrate; and

a projection system (e.g., a reflective projection system) PS configured to project a pattern imparted to the radiation beam B by patterning device MA onto a target portion C (e.g., comprising one or more dies) of the substrate W.

The illumination system may include various types of optical components, such as refractive, reflective, magnetic, electromagnetic, electrostatic or other types of optical components, or any combination thereof, for directing, shaping, or controlling radiation.

The support structure MT holds the patterning device MA in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system.

The term “patterning device” should be broadly interpreted as referring to any device that can be used to impart a radiation beam with a pattern in its cross-section such as to create a pattern in a target portion of the substrate. The pattern imparted to the radiation beam may correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam that is reflected by the mirror matrix.

The projection system, like the illumination system, may include various types of optical components, such as refractive, reflective, magnetic, electromagnetic, electrostatic or other types of optical components, or any combination thereof, as appropriate for the exposure radiation being used, or for other factors such as the use of a vacuum. It may be desired to use a vacuum for EUV radiation since other gases may absorb too much radiation. A vacuum environment may therefore be provided to the whole beam path with the aid of a vacuum wall and vacuum pumps.

As here depicted, the apparatus is of a reflective type (e.g., employing a reflective mask).

The lithographic apparatus may be of a type having two (dual stage) or more substrate tables (and/or two or more mask tables). In such “multiple stage” machines the additional tables may be used in parallel, or preparatory steps may be carried out on one or more tables while one or more other tables are being used for exposure.

Referring to FIG. 1, the illuminator IL receives an extreme ultra violet radiation beam from the source module SO. Methods to produce EUV light include, but are not necessarily limited to, converting a material into a plasma state that has at least one element, e.g., xenon, lithium or tin, with one or more emission lines in the EUV range. In one such method, often termed laser produced plasma (“LPP”) the required plasma can be produced by irradiating a fuel, such as a droplet, stream or cluster of material having the required line-emitting element, with a laser beam. The source module SO may be part of an EUV radiation system including a laser, not shown in FIG. 1, for providing the laser beam exciting the fuel. The resulting plasma emits output radiation, e.g., EUV radiation, which is collected using a radiation collector, disposed in the source module. The laser and the source module may be separate entities, for example when a CO2 laser is used to provide the laser beam for fuel excitation.

In such cases, the laser is not considered to form part of the lithographic apparatus and the radiation beam is passed from the laser to the source module with the aid of a beam delivery system comprising, for example, suitable directing mirrors and/or a beam expander. In other cases the source may be an integral part of the source module, for example when the source is a discharge produced plasma EUV generator, often termed as a DPP source.

The illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross-section.

The radiation beam B is incident on the patterning device (e.g., mask) MA, which is held on the support structure (e.g., mask table) MT, and is patterned by the patterning device. After being reflected from the patterning device (e.g., mask) MA, the radiation beam B passes through the projection system PS, which focuses the beam onto a target portion C of the substrate W. With the aid of the second positioner PW and position sensor PS2 (e.g., an interferometric device, linear encoder or capacitive sensor), the substrate table WT can be moved accurately, e.g., so as to position different target portions C in the path of the radiation beam B. Similarly, the first positioner PM and another position sensor PS1 can be used to accurately position the patterning device (e.g., mask) MA with respect to the path of the radiation beam B. Patterning device (e.g., mask) MA and substrate W may be aligned using mask alignment marks M1, M2 and substrate alignment marks P1, P2.

FIG. 2 shows an embodiment of the lithographic apparatus in more detail, including a radiation system 42, the illumination system IL, and the projection system PS. The radiation system 42 as shown in FIG. 2 is of the type that uses a laser-produced plasma as a radiation source. EUV radiation may be produced by a gas or vapor, for example Xe gas, Li vapor or Sn vapor in which a very hot plasma is created to emit radiation in the EUV range of the electromagnetic spectrum. The very hot plasma is created by causing an at least partially ionized plasma by, for example, optical excitation using CO2 laser light. Partial pressures of, for example, 10 Pa of Xe, Li, Sn vapor or any other suitable gas or vapor may be required for efficient generation of the radiation. In an embodiment, Sn is used to create the plasma in order to emit the radiation in the EUV range.

The radiation system 42 embodies the function of source SO in the apparatus of FIG. 1. Radiation system 42 comprises a low pressure chamber, referred herein as a source chamber 47, in this embodiment not only substantially enclosing a source of EUV radiation, but also collector 50 that, in the example of FIG. 2, is a normal-incidence collector, for instance a multi-layer mirror.

As part of an LPP radiation source, a laser system 61 is constructed and arranged to provide a laser beam 63, which is delivered by a beam delivering system 65 through an aperture 67 provided in the collector 50. Also, the radiation system includes a target material 69, such as Sn or Xe, which is supplied by target material supply 71. The beam delivering system 65, in this embodiment, is arranged to establish a beam path focused substantially upon a desired plasma formation position 73.

In operation, the target material 69, which may also be referred to as fuel, is supplied by the target material supply 71 in the form of droplets. When such a droplet of the target material 69 reaches the plasma formation position 73, the laser beam 63 impinges on the droplet and an EUV radiation-emitting plasma forms inside the source chamber 47. In the case of a pulsed laser, this involves timing the pulse of laser radiation to coincide with the passage of the droplet through the position 73. As mentioned, the fuel may be for example xenon (Xe), tin (Sn) or lithium (Li). These create a highly ionized plasma with electron temperatures of several 10's of eV. Higher energy EUV radiation may be generated with other fuel materials, for example Tb and Gd. The energetic radiation generated during de-excitation and recombination of these ions includes the wanted EUV, which is emitted from the plasma at position 73. The plasma formation position 73 and the aperture 52 are located at first and second focal points of collector 50, respectively and the EUV radiation is focused by the normal-incidence collector mirror 50 onto the intermediate focus point IF.

The beam of radiation emanating from the source chamber 47 traverses the illumination system IL via so-called normal incidence reflectors 53, 54, as indicated in FIG. 2 by the radiation beam 56. The normal incidence reflectors direct the beam 56 onto a patterning device (e.g., reticle or mask) positioned on a support (e.g., reticle or mask table) MT. A patterned beam 57 is formed, which is imaged by projection system PS via reflective elements 58, 59 onto a substrate carried by wafer stage or substrate table WT. More elements than shown may generally be present in illumination system IL and projection system PS. For example there may be one, two, three, four or even more reflective elements present than the two elements 58 and 59 shown in FIG. 2. Radiation collectors similar to radiation collector 50 are known from the prior art.

As the skilled reader will know, reference axes X, Y and Z may be defined for measuring and describing the geometry and behavior of the apparatus, its various components, and the radiation beams 55, 56, 57. At each part of the apparatus, a local reference frame of X, Y and Z axes may be defined. The Z axis broadly coincides with the direction of optical axis O at a given point in the system, and is generally normal to the plane of a patterning device (reticle) MA and normal to the plane of substrate W. In the source module (apparatus) 42, the X axis coincides broadly with the direction of fuel stream (69, described below), while the Y axis is orthogonal to that, pointing out of the page as indicated. On the other hand, in the vicinity of the support structure MT that holds the reticle MA, the X axis is generally transverse to a scanning direction aligned with the Y axis. For convenience, in this area of the schematic diagram FIG. 2, the X axis points out of the page, again as marked. These designations are conventional in the art and will be adopted herein for convenience. In principle, any reference frame can be chosen to describe the apparatus and its behavior.

To deliver the fuel, which for example is liquid tin, a droplet generator or target material supply 71 is arranged within the source chamber 47, to fire a stream of droplets towards the plasma formation position 73. In operation, laser beam 63 may be delivered in a synchronism with the operation of target material supply 71, to deliver impulses of radiation to turn each fuel droplet into a plasma. The frequency of delivery of droplets may be several kilohertz, or even several tens or hundreds of kilohertz. In practice, laser beam 63 may be delivered by a laser system 61 in at least two pulses: a pre pulse PP with limited energy is delivered to the droplet before it reaches the plasma location, in order to vaporize the fuel material into a small cloud, and then a main pulse MP of laser energy is delivered to the cloud at the desired location, to generate the plasma. In a typical example, the diameter of the plasma is about 2-3 mm. A trap 72 is provided on the opposite side of the enclosing structure 47, to capture fuel that is not, for whatever reason, turned into plasma.

Laser system 61 in may be for example of the MOPA (Master Oscillator Power Amplifier) type. Such a laser system 61 includes a “master” laser or “seed” laser, followed by a power amplifier system PA, for firing a main pulse of laser energy towards an expanded droplet cloud, and a pre pulse laser for firing a pre pulse of laser energy towards a droplet. A beam delivery system 24 is provided to deliver the laser energy 63 into the source chamber 47. In practice, the pre-pulse element of the laser energy may be delivered by a separate laser. Laser system 61, target material supply 71 and other components can be controlled by a controller (not shown separately. The controller performs many control functions, and has sensor inputs and control outputs for various elements of the system. Sensors may be located in and around the elements of radiation system 42, and optionally elsewhere in the lithographic apparatus. In some embodiments of the present invention, the main pulse and the pre pulse are derived from a same laser. In other embodiment of the present invention, the main pulse and the pre-pulse are derived from different lasers that are independent from each other but controlled to operate synchronously. A problem that can arise in the LPP source apparatus is that optical elements of the laser beam deliver system 65 will become contaminated with debris from the plasma. In particular a final optical element, be it a lens or a mirror, is directly exposed to particles of fuel ejected from the plasma. A refractive (transmissive) element will quickly become obscured by tin deposits, leading to reduced transmission of the laser radiation and undesired heating. A reflective final element, such as a copper mirror, may be more tolerant of Sn deposits for time, but will need cleaning eventually to maintain efficiency of reflection and focusing. Laser system 61 may also be a solid-state laser such as an Nd:YAG type laser which may be used for firing a main pulse of laser energy directly towards the fuel droplet.

In order to block as much contamination as possible, a contamination trap 80 of some sort may be provided between the plasma formation site 73 and optical elements of the beam delivery system 65.

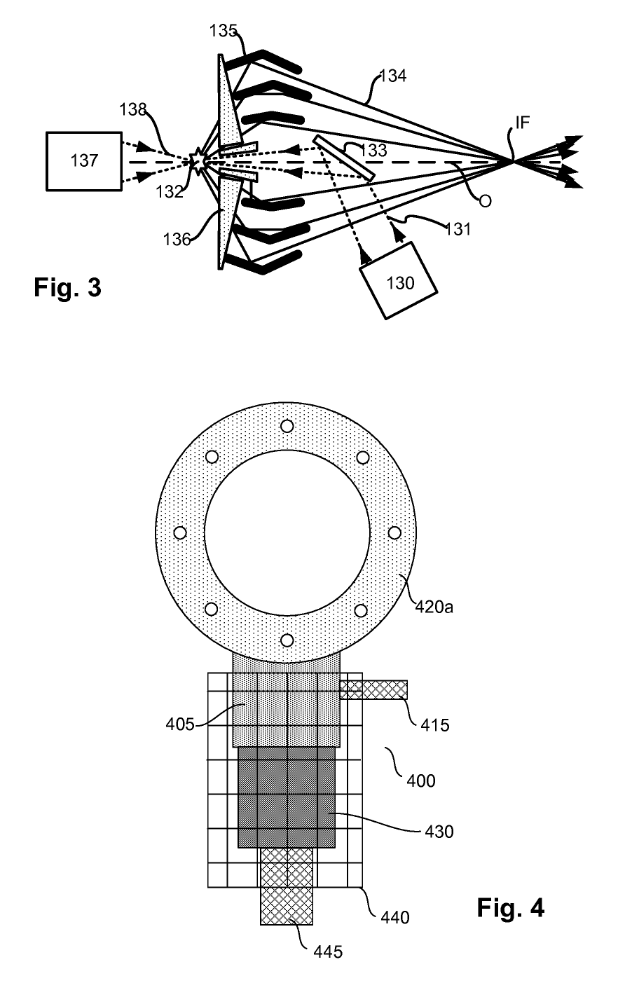

FIG. 3 shows an alternative LPP source arrangement that may be used in place of that illustrated in FIG. 2. A main difference is that the main pulse laser beam is directed onto the fuel droplet from the direction of the intermediate focus point IF, such that the collected EUV radiation is that, which is emitted generally in the direction from, which the main laser pulse was received.

FIG. 3 shows the main laser beam delivery system 130 emitting a main pulse beam 131 delivered to a plasma formation position 132. At least one optical element of the beam delivery system, in this case a folding mirror 133 is located on the optical axis between plasma position 132 and the intermediate focus. (The term “folding” here refers to folding of the beam, not folding of the mirror.) The EUV radiation 134 emitted by a plasma at position 132, or at least the major portion that is not directed back along the optical axis O into the folding mirror 133 is collected by a grazing incidence collector 135. This type of collector is known already, but is generally used in discharge produced plasma (DPP) sources, not LPP sources. Also shown is a debris trap 136. A pre-pulse laser 137 is provided to deliver a pre-pulse laser beam 138 to fuel droplets. In this example, the pre-pulse energy is delivered to the side of the fuel droplet that faces away from the intermediate focus point IF. It should be understood that the elements shown in this schematic diagram are not to scale.

The source chamber 47 may comprise a number of radiation transmission assemblies, or “viewports”, through which radiation may be transmitted thereby allowing optical metrology devices to perform measurements and monitoring operations performed for process control. Such devices may measure formation and position of the fuel droplet, and plasma position, allowing servo control and droplet steering.

The viewports may comprise vacuum gate valves, having a membrane or pellicle separating the low pressure source chamber 47 environment from the surrounding (external) environment. Gate valves were sometimes provided to enable swapping of the pellicles without breaking the vacuum. In order to achieve this, the gate valves were provided with a vacuum line for venting and pumping of the valve. The pellicle transmits radiation so as to enable measuring/monitoring to be performed using modules outside of the source chamber 47. The radiation transmitted by a pellicle may comprise laser radiation, such as in the case of the BLM that provides light to enable other monitoring cameras to, e.g., the droplet, or visible/infrared radiation in the case of camera ports. Other pellicles may need to transmit generated EUV radiation generated within the source and may therefore need to be particularly thin.

During the operation of the EUV radiation source, the source chamber 47 (which is the plasma generating chamber of the EUV radiation source) is exposed to significant amounts of fuel (e.g., tin) debris. Over time, this fuel contaminates the pellicle surface and therefore reduces the transmission of the generated EUV through the viewports, thereby preventing the optical metrology devices from making their measurements. This may be addressed by replacing the viewports when they are contaminated. However, even with the provision of gate valves, the metrology viewports are not always easily reachable, and pellicle removal may require source downtime of 48 hours or longer, depending on its position. A low pressure chamber apparatus is generally speaking an apparatus comprising a low pressure chamber in which a radiation is generated or transmitted. The low pressure chamber apparatus may comprise the plasma generating chamber (source chamber 47) of the EUV radiation source.

It is therefore proposed to clean the viewports, and in particular the pellicles comprised therein, with hydrogen radicals. This may be done using a viewport cleaner that comprises a hydrogen radical generator. The hydrogen radical generator generates hydrogen radicals that cleanse the viewport. In some embodiments, only a single viewport cleaner, comprising a hydrogen radical generator, may be provided and the hydrogen radicals generated using the single hydrogen radical generator may be directed towards one or more viewports, for example, by appropriate gas flow, diffusion or the like. However, in a preferred embodiment, each viewport is provided with a separate viewport cleaner having a hydrogen radical generator. Each viewport cleaner may replace a viewport gate valve of the source chamber 47.

The viewport or pellicle cleaner creates hydrogen radicals from molecular hydrogen by cracking them with a hot filament. They may use the same technique as hydrogen radical generators that are sometimes used for carbon cleaning in the EUV lithographic apparatus. The hydrogen radicals react with the deposited tin such that the deposited becomes tin volatile again. The volatile tin (tin hydrates) can be pumped away using the existing pumps within the source.

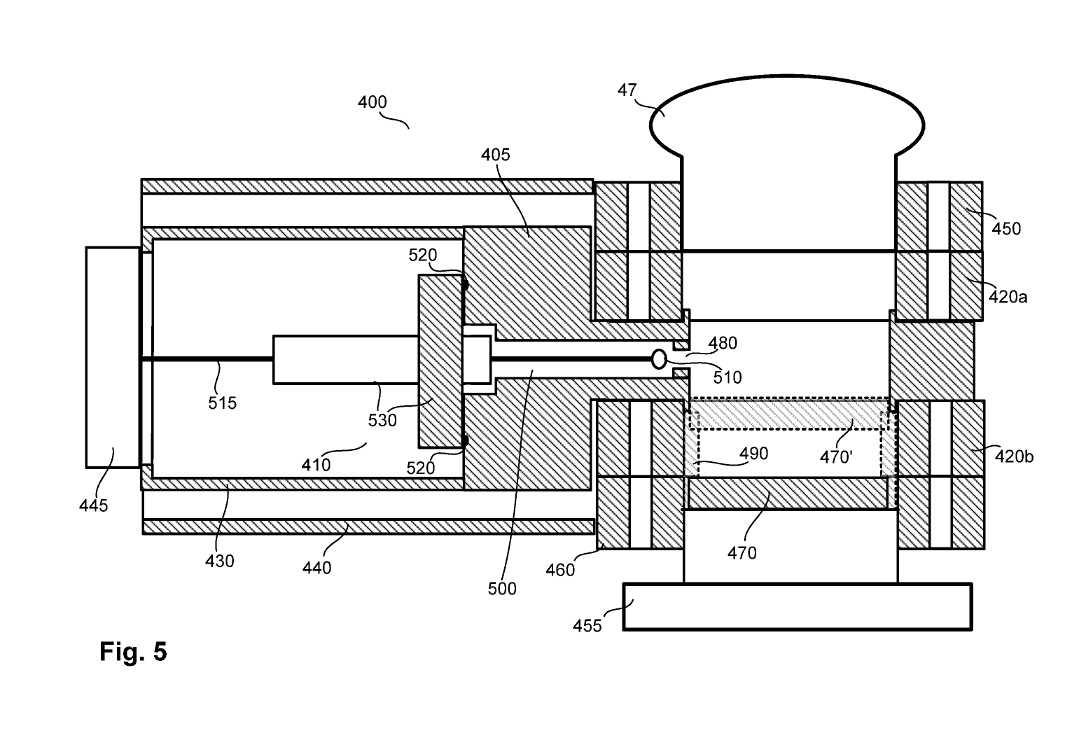

FIGS. 4 and 5 show a cleaning apparatus, referred herein as a viewport cleaner 400, in top-down view and cross-section respectively. The viewport cleaner 400 comprises a main housing 405, a hydrogen radical generator 410 having an inlet 415 for receiving molecular hydrogen, top and bottom vacuum flanges 420a, 420b, which form a vacuum connection flange assembly, a filament protection box 430 which is a contamination shielding configured to shield the filament back assembly 530 from debris from the source chamber 47 (i.e. the low pressure chamber), a heat shielding (a mesh in this example) 440 and an electrical connector 445. A connection assembly comprising the vacuum connection flange assembly is therefore used to connect the hydrogen radical generator 410 to the radiation transmission assembly (i.e. the viewport) to be cleaned. The vacuum flange assembly comprises the top vacuum flange 420a referred to as first vacuum flange, for connection to a radiation transmission flange referred to as viewport flange 450, forming part of the source chamber 47, and the bottom vacuum flange 420b referred to as second vacuum flange for connection to a module flange 460 forming part of an external module, such that the vacuum connection flange assembly is located (connected) between the radiation transmission flange 450 and the module flange 460. In this way the viewport (i.e the radiation transmission assembly) comprises the viewport flange 450, the module flange 460 and the vacuum connection flange assembly 420a and 420b.

FIG. 5 also shows the viewport interfaces. Shown is the viewport flange 450 of the source chamber 47. Normally, a metrology module 455 (also referred to as an external metrology module) is connected to the viewport flange 450 via a gate valve. However, in the embodiment depicted here, the metrology module 455 is connected to the viewport via the viewport cleaner 400. To make the connection, the metrology module 455 comprises a module flange 460. The module flange 460 comprises pellicle 470, which separates the metrology module 455 from the vacuum environment of the source chamber 47. A modification is also shown (dotted lines) in which the pellicle 470′ is raised to be nearer the hydrogen radical generator outlet 480 by a pellicle holder 490.

The hydrogen radical generator 410 may comprise a generator compartment 500 (referred further as “compartment”) in which the hydrogen radicals are generated, the compartment 500 having a metal filament 510 located therein. The metal filament 510 may, for example be tungsten, or indeed any other metal, which can withstand the temperature required to atomize molecular hydrogen. The filament is shown as having a coil-like shape in the Figure, but in other embodiments the filament may take a different form. The compartment is configured to form part of the low pressure chamber (i.e. source chamber 47) environment.

The metal filament 510 may be in connection with, controlled by and driven by a controller (not shown). The controller is able to control the temperature of the metal filament 510 by appropriate control of a driving current provided to and passing through the metal filament 510. Metal filament 510 may be connected to an electrical supply via electrical connector 445 and power lead 515.

The compartment 500 is provided with inlet 415 and outlet 480 for allowing the passage of gas or the like (e.g., particles, atoms, molecules) into and out of the compartment 500 respectively. The compartment 500 may be effectively within the source chamber 47 environment, and therefore sealed other than the inlet 415 (connected to a molecular hydrogen supply) and the outlet, which feeds into the viewport interface of the source chamber 47. Although not shown in the Figure, the hydrogen radical generator 410 may be provided with or be used in conjunction with one or more pumps for drawing or blowing gas or the like into the hydrogen radical generator and/or ejecting gas out of and away from the hydrogen radical generator.

In use, molecular hydrogen from inlet 415 is passed into or drawn into the compartment 500 and passed over (e.g., through and/or around) the metal filament 510. This is undertaken when the temperature of the metal filament 510 is an atomization temperature (e.g., 1200° C.-2500° C.), sufficient to atomize the molecular hydrogen and to generate hydrogen radicals for use in cleansing the viewport, and in particular the pellicle 470, 470′.

The design of the viewport cleaner 400 is such that the molecular hydrogen flowing from compartment 500 creates a flow with high velocity at outlet 480. This design is called a Péclet tube and results in the pressure around the filament 510 within the compartment 500 being higher than outside of outlet 480 in the source chamber 47, thereby protecting the filament 510 against contamination or damage by particles (such as the tin fuel). This improves lifetime and aids constant operation of the viewport cleaner 400.

The cleaning speed depends mainly upon the amount of hydrogen radicals generated, which in turn depends upon the filament temperature. The design of the viewport cleaner 400 proposed herein enables use of a sufficiently low filament temperature, requiring correspondingly low electric power, that cooling via convection is sufficient to meet human safety regulations. Therefore the filament temperature may be kept below 1600° C., below 1400° C. or below 1200° C., for example. The design of the pellicle cleaner ensures that a large proportion of the radicals generated reach the correct location and that not too many radicals are “lost” before reaching the pellicle. The filament 510 and outlet 480 is close to the pellicle, and the radicals will be carried by the hydrogen flow through outlet 480.

As shown, in one embodiment the pellicle 470′ may be positioned closer to the outlet 480 by way of a pellicle holder 490, which forms part of the metrology apparatus flange assembly 460. This can improve the cleaning efficiency.

The filament back assembly 530, bounded within filament protection box 430, electrical connector 445 and housing 405, is provided with a vacuum seal 520. The vacuum seal is thus provided between the filament back assembly 530 and the (generator) compartment 500. In the example shown, vacuum seal 520 is an O-ring seal positioned within a groove in the housing 405, and which is pressed so as to be vacuum tight by the filament back assembly 530. The position of the seal 520 within a groove protects it against hydrogen radicals and filament heat and light radiation. By way of comparison, hydrogen radical generators used within the lithographic apparatus for mirror cleaning tend not to have a vacuum sealed filament assembly, as the filament back assembly together with the hydrogen radical generators is used completely within a vacuum environment.

To reduce production costs, the filament and filament back assembly can be the same or similar to that already used to clean mirrors and other optics within the lithographic apparatus. Specific adaptions for this application may include:

The filament back assembly may form part of the vacuum compartment. In this way compartment 500 comprising filament 510 is effectively within the same low-vacuum environment of the source chamber 47.

No water cooling is needed for operation. The cooling of the cleaner is achieved through convection towards the lab environment. Hydrogen radical generators used for mirror cleaning etc. are normally located in a vacuum environment thereby preventing effective convection to that environment, and are therefore normally water cooled. Also the filament temperature can be kept low, as previously mentioned.

The housing 405 and filament protection box 430 are designed such that the filament is protected against tin debris and tin vapor, thereby improving filament lifetime.

The viewport cleaner 400 can operate at source pressure conditions (which are higher than the EUV lithographic apparatus conditions). Also the filament should be sufficiently strong for the flow and pressure conditions present within the viewport cleaner, which may be higher than in hydrogen radical generators used entirely within a vacuum environment.

It has been shown that the viewport cleaner disclosed herein can increase the uptime of the EUV radiation source by significant margin.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The term “lens”, where the context allows, may refer to any one or combination of various types of optical components, including refractive, reflective, magnetic, electromagnetic and electrostatic optical components.

While specific embodiments of the invention have been described above,

it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1. A cleaning apparatus configured to clean a radiation transmission assembly or part thereof, said radiation transmission assembly providing for radiation transmission to and/or from a low pressure chamber environment, said cleaning apparatus comprising:
a hydrogen radical generator configured to generate hydrogen radicals for use in cleaning said radiation transmission assembly or part thereof; and
a connection assembly for connection of the hydrogen radical generator to said radiation transmission assembly.

2. The cleaning apparatus of claim 1, wherein said hydrogen radical generator comprises a generator compartment in which said hydrogen radicals are generated, said generator compartment being configured in use to form part of the low pressure chamber environment.

3. The cleaning apparatus of claim 1, wherein said hydrogen radical generator comprises a filament configured to heat generator compartment to a temperature sufficient to atomize molecular hydrogen passing over the filament, so as to generate said hydrogen radicals, and a filament back assembly located between said filament and an electrical source connector, said cleaning apparatus comprising contamination shielding configured to shield said filament back assembly from debris from within said low pressure chamber.

4. The cleaning apparatus of claim 3, wherein a vacuum seal is provided between the filament back assembly and said generator compartment.

5. The cleaning apparatus of claim 2, wherein said generator compartment comprises an outlet through which said hydrogen radicals are emitted, said the generator compartment and outlet being configured such that the pressure within the generator compartment is higher than on the outside of said outlet.

6. The cleaning apparatus of claim 1, of claim 1, wherein said cleaning apparatus comprises heat shielding.

7. The cleaning apparatus of claim 1, wherein said connection assembly comprises a vacuum connection flange assembly.

8. The cleaning apparatus of claim 7, wherein said vacuum connection flange assembly comprises a first vacuum flange for connection to a radiation transmission flange forming part of the low pressure chamber and a second vacuum flange for connection to a module flange forming part of an external module, such that said vacuum connection flange assembly in use is located between said radiation transmission flange and said module flange such that said radiation transmission assembly comprises said radiation transmission flange, said module flange and said vacuum connection flange assembly.

9. The cleaning apparatus of claim 1, wherein said radiation transmission assembly comprises a pellicle separating the low pressure chamber environment from an external environment, said cleaning apparatus being operable to clean a surface of said pellicle.

10. The cleaning apparatus of claim 9, further comprising a pellicle holder configured to hold the pellicle at a location in the vicinity of an outlet of said hydrogen radical generator, through which said hydrogen radicals are ejected.

11. The cleaning apparatus of claim 1, wherein said low pressure chamber comprises the plasma generating chamber of an EUV radiation source.

12. A low pressure chamber apparatus, comprising: one or more radiation transmission assemblies through which radiation may be transmitted for monitoring operations,
wherein one or more of said radiation transmission assemblies comprises a cleaning apparatus configured to clean its corresponding radiation transmission assembly or part thereof, each cleaning apparatus comprising a hydrogen radical generator configured to generate hydrogen radicals for use in cleaning said radiation transmission assembly or part thereof.

13. The low pressure chamber apparatus of claim 12, wherein said cleaning apparatus comprises the cleaning apparatus comprising:
a hydrogen radical generator configured to generate hydrogen radicals for use in cleaning said radiation transmission assembly or part thereof; and
a connection assembly for connection of the hydrogen radical generator to said radiation transmission assembly.

14. The low pressure chamber apparatus of claim 12, wherein said low
pressure chamber apparatus comprises:
a radiation transmission flange; and
an external metrology module comprising a module flange;
and said cleaning apparatus comprises a vacuum connection flange assembly connected between said radiation transmission flange and said metrology flange such that said radiation transmission assembly comprises said radiation transmission flange, said module flange and said vacuum connection flange assembly.

15. The low pressure chamber apparatus of claim 14, wherein said radiation transmission assembly comprises a pellicle separating the low pressure chamber environment from the external environment, said cleaning apparatus being operable to clean a surface of said pellicle.

16. The low pressure chamber apparatus of claim 15, wherein said pellicle is comprised within the module flange.

17. The low pressure chamber apparatus of claim 12, wherein said low pressure chamber apparatus comprises the plasma generating chamber of an EUV radiation source.
